(19) United States
(12) Patent Application Publication
(10) Pub. No.: US 2017/0084470 A1
(43) Pub. Date: Mar. 23, 2017

(54) SUBSTRATE PROCESSING APPARATUS AND CLEANING METHOD OF PROCESSING CHAMBER

(71) Applicant: Tokyo Electron Limited, Tokyo (JP)

(72) Inventors: Hiroyuki Suzuki, Koshi City (JP); Takahisa Otsuka, Koshi City (JP); Kiyohisa Tateyama, Koshi City (JP); Takashi Nakazawa, Koshi City (JP)

(21) Appl. No.: 15/263,451

(22) Filed: Sep. 13, 2016

(30) Foreign Application Priority Data
Sep. 18, 2015 (JP) 2015-185642
Mar. 24, 2016 (JP) 2016-060352

(51) Int. Cl. H01L 21/67; F26B 3/20; B08B 3/10; B08B 3/08; B08B 9/08

(52) U.S. Cl. CPC H01L 21/67051; H01L 21/67075; B08B 3/08; B08B 9/08; B08B 3/10; F26B 3/20

(57) ABSTRACT

A drying time after cleaning a surface of a cleaning target including a wall which constitutes a processing chamber of a substrate processing apparatus and a device provided within the processing chamber can be shortened. After performing a cleaning process of dissolving a removal target adhering to the surface of the cleaning target with water by discharging the water into the processing chamber 20 and allowing the surface of the cleaning target 42, 20a and 53 to be wet with the water, a solvent supplying process of supplying a solvent having higher volatility than the water toward the water adhering to the surface of the cleaning target is performed by discharging the solvent into the processing chamber. Then, a drying process of drying the surface of the cleaning target is performed.

### CROSS-REFERENCE TO RELATED APPLICATION

This application claims the benefit of Japanese Patent Application Nos. 2016-060352 and 2015-185642 filed on Mar. 24, 2016 and Sep. 18, 2015, respectively, the entire disclosures of which are incorporated herein by reference.

### TECHNICAL FIELD

The embodiments described herein pertain generally to a technique of cleaning an inside of a processing chamber in a substrate processing apparatus configured to perform a liquid processing on a substrate by supplying a processing liquid onto the substrate.

### BACKGROUND

In a manufacturing process of a semiconductor device, a liquid processing such as a wet etching process or a chemical liquid cleaning process is performed on a substrate such as a semiconductor wafer or the like. Such a liquid processing is performed by supplying a processing liquid onto a surface of the substrate which is being rotated. Most of the processing liquid supplied onto the substrate is collected by a cylindrical liquid collecting member called a “recovery cup”. However, the processing liquid which is splashed is scattered over the liquid collecting member, and then, adheres to an inner wall of a processing chamber or a device within the processing chamber. If this processing liquid adhering thereto is left without being removed, the processing liquid may be dried and crystallized to cause particle generation. To avoid this problem, the inner wall of the processing chamber and the device within the processing chamber are cleaned periodically with the shower of a cleaning liquid, e.g., pure water (see, for example, Patent Document 1).

If the pure water is adhering to the inner wall of the processing chamber, humidity within the processing chamber is increased as the pure water evaporated (vaporized). Since the substrate is not dried well after the liquid processing in an atmosphere where the humidity is not sufficiently low, the processing cannot be resumed until the pure water is sufficiently dried. Further, since it takes time to dry the pure water, a downtime of the substrate processing apparatus is lengthened.

Patent Document 1: Japanese Patent Laid-open Publication No. H11-297652

### SUMMARY

In view of the foregoing, exemplary embodiments provide a technique capable of shortening a drying time after cleaning a processing chamber.

In one exemplary embodiment, a substrate processing apparatus includes a processing chamber; a substrate holding unit provided within the processing chamber and configured to hold a substrate; a processing liquid nozzle configured to supply a processing liquid onto the substrate held by the substrate holding unit; and a cleaning fluid discharging unit configured to discharge water for cleaning a surface of a cleaning target including a wall of the processing chamber and a device provided within the processing chamber and a solvent having higher volatility than the water and replacing the water adhering to the surface of the cleaning target into an internal space of the processing chamber.

In another exemplary embodiment, there is provided a processing chamber cleaning method of cleaning a cleaning target within a processing chamber of a substrate processing apparatus. The processing chamber cleaning method includes a cleaning process of cleaning a removal target adhering to a surface of the cleaning target by discharging water into the processing chamber and allowing the cleaning target to be wet with the water; a solvent supplying process of supplying a solvent having higher volatility than the water toward the water adhering to the surface of the cleaning target by discharging the solvent into the processing chamber; and a drying process of drying the surface of the cleaning target.

In accordance with the exemplary embodiments, by supplying the solvent toward the water adhering to the surface of the cleaning target within the chamber after the surface of the cleaning target is cleaned with the water, the surface of the cleaning target is covered with the solvent, so that the surface of the cleaning target can be dried rapidly.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a plan view illustrating an outline of a substrate processing system according to an exemplary embodiment;

FIG. 2 is a longitudinal cross sectional view illustrating a schematic configuration of a processing chamber according to a first exemplary embodiment;

FIG. 3 is a horizontal cross sectional view illustrating a schematic configuration of the processing chamber according to the first exemplary embodiment;

FIG. 4 is a perspective view showing a cleaning jig;

FIG. 5 is the same schematic plan view as FIG. 1, illustrating arrangement of a jig accommodating unit;

FIG. 6 is a piping diagram illustrating a modification example of a solvent supply unit and a cleaning water supply unit;

FIG. 7 is a piping diagram illustrating a modification example of a low-humidity gas supply unit;

FIG. 8 is a schematic perspective view illustrating a heater provided at a wall of the processing chamber;

FIG. 9 is a longitudinal cross sectional view illustrating a schematic configuration of a processing chamber according to a second exemplary embodiment;

FIG. 10 is a longitudinal cross sectional view illustrating a schematic configuration in the vicinity of a bottom plate and an upper portion of a liquid recovery cup shown in FIG. 9;

FIG. 11 is a perspective view illustrating a specific example of a nozzle arm shown in FIG. 9; and

FIG. 12 is a diagram for describing a pinning effect of wetting.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

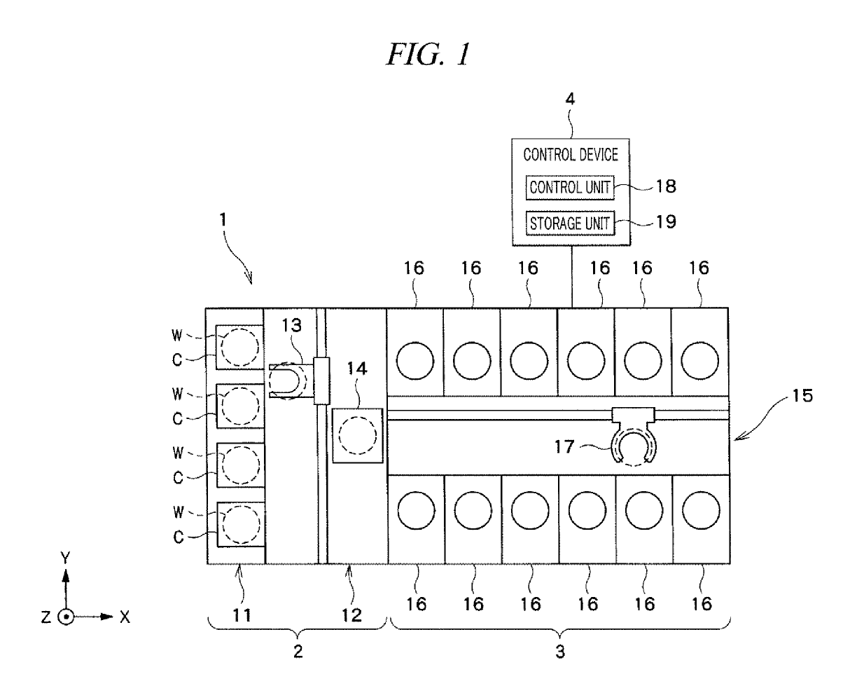

FIG. 1 is a plan view illustrating an outline of a substrate processing system provided with a processing unit according to an exemplary embodiment of the present disclosure. In the following, in order to clarify positional relationships, the X-axis, Y-axis and Z-axis which are orthogonal to each other will be defined. The positive Z-axis direction will be regarded as a vertically upward direction.

As illustrated in FIG. 1, a substrate processing system 1 includes a carry-in/out station 2 and a processing station 3. The carry-in/out station 2 and the processing station 3 are provided adjacent to each other.

The carry-in/out station 2 is provided with a carrier placing section 11 and a transfer section 12. In the carrier placing portion 11, a plurality of carriers C is placed to accommodate a plurality of substrates (semiconductor wafers in the present exemplary embodiment) (hereinafter, referred to as “wafers W”) horizontally.

The transfer section 12 is provided adjacent to the carrier placing section 11, and provided with a substrate transfer device 13 and a delivery unit 14. The substrate transfer device 13 is provided with a wafer holding mechanism configured to hold the wafer W. Further, the substrate transfer device 13 is movable horizontally and vertically and pivotable around a vertical axis, and transfers the wafers W between the carriers C and the delivery unit 14 by using the wafer holding mechanism.

The processing station 3 is provided adjacent to the transfer section 12. The processing station 3 is provided with a transfer section 15 and a plurality of processing units 16. The plurality of processing units 16 is arranged at both sides of the transfer section 15.

The transfer section 15 is provided with a substrate transfer device 17 therein. The substrate transfer device 17 is provided with a wafer holding mechanism configured to hold the wafer W. Further, the substrate transfer device 17 is movable horizontally and vertically and pivotable around a vertical axis. The substrate transfer device 17 transfers the wafers W between the delivery unit 14 and the processing units 16 by using the wafer holding mechanism.

The processing units 16 perform a predetermined substrate processing on the wafers W transferred by the substrate transfer device 17.

Further, the substrate processing system 1 is provided with a control device 4. The control device 4 is, for example, a computer, and includes a control unit 18 and a storage unit 19. The storage unit 19 stores a program that controls various processings performed in the substrate processing system 1. The control unit 18 controls the operations of the substrate processing system 1 by reading and executing the program stored in the storage unit 19.

Further, the program may be recorded in a computer-readable recording medium, and installed from the recording medium to the storage unit 19 of the control device 4. The computer-readable recording medium may be, for example, a hard disc (HD), a flexible disc (FD), a compact disc (CD), a magnet optical disc (MO), or a memory card.

In the substrate processing system 1 configured as described above, the substrate transfer device 13 of the carry-in/out station 2 first takes out a wafer W from a carrier C placed in the carrier placing section 11, and then places the taken wafer W on the delivery unit 14. The wafer W placed on the delivery unit 14 is taken out from the delivery unit 14 by the substrate transfer device 17 of the processing station 3 and carried into a processing unit 16.

The wafer W carried into the processing unit 16 is processed by the processing unit 16, and then, carried out from the processing unit 16 and placed on the delivery unit 14 by the substrate transfer device 17. After the processing of placing the wafer W on the delivery unit 14, the wafer W returns to the carrier C of the carrier placing section 11 by the substrate transfer device 13.

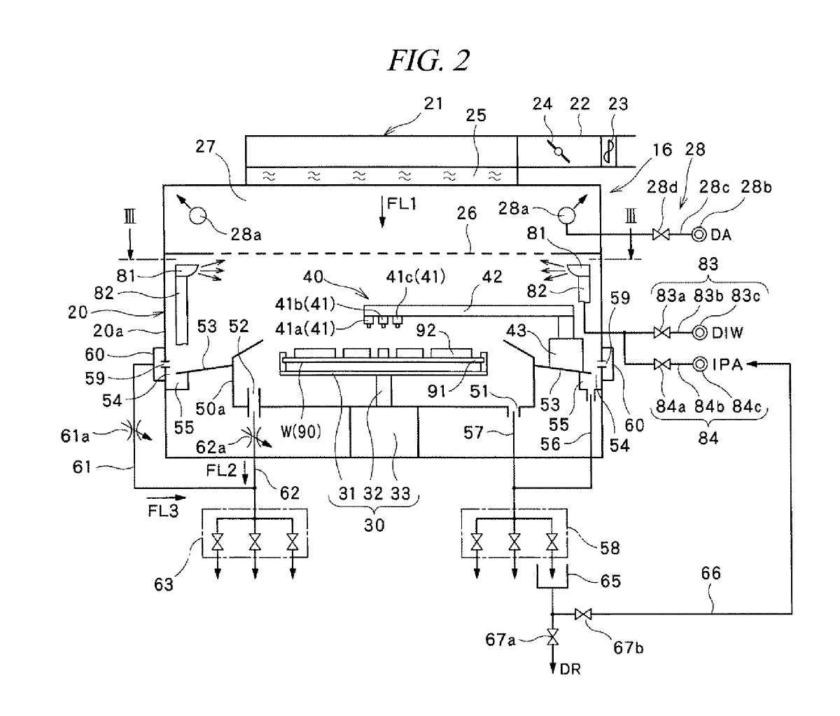

Now, a configuration of the processing unit 16 will be described with reference to FIG. 2. The processing unit 16 includes a chamber 20, a substrate holding mechanism 30, a processing fluid supply unit 40 and a liquid recovery cup 50.

The chamber 20 accommodates therein the substrate holding mechanism 30, the processing fluid supply unit 40 and the liquid recovery cup 50. A FFU (Fan Filter Unit) 21 is provided at a ceiling portion of the chamber 20.

The FFU 21 is includes a duct 22; a fan 23 and a damper 24 (flow rate control valve) which are arranged within the duct 22 in this sequence from an upstream side thereof; and a filter 25 such as an ULPA filter. By rotating the fan 23, air in a clean room is introduced into the duct 22, and the air (clean air) from which particles are removed by the filter 25 is discharged downwards into the chamber 20.

A rectifying plate 26 is provided in an upper portion of the chamber (processing chamber) 20. The rectifying plate 26 is formed of a plate provided with a multiple number of holes. A low-humidity gas supply unit 28 configured to supply a low-humidity gas, e.g., dry air DA is provided in a space 27 above the rectifying plate 26 within the chamber 20. The low-humidity gas supply unit 28 includes a nozzle 28a provided within the space 27; a gas supply path 28c connecting the nozzle 28a and a low-humidity gas supply source 28b; and a flow control device 28d provided at a portion of the gas supply path 28c. The flow control device 28d includes an opening/closing valve, a flow rate control valve, and so forth. The low-humidity gas may be a nitrogen gas.

The substrate holding mechanism 30 is equipped with a substrate holding unit 31, a shaft unit 32 and a rotation driving unit 33. The substrate holding unit 31 is configured to hold the wafer W horizontally. By rotating the substrate holding unit 31 via the shaft unit 32 through the rotation driving unit 33, the wafer W held by the substrate holding unit 31 can be rotated around a vertical axis line.

The processing fluid supply unit 40 is provided with a multiple number of nozzles (processing fluid nozzles) 41 each configured to supply a processing fluid (processing liquid or processing gas) toward the wafer W. In the present exemplary embodiment, the multiple number of nozzles include a chemical liquid nozzle 41a, a rinse nozzle 41b, and a solvent nozzle 41c. The multiple number of nozzles may further include another chemical liquid nozzle, another rinse nozzle, a two-fluid nozzle, a drying gas nozzle, and so forth.

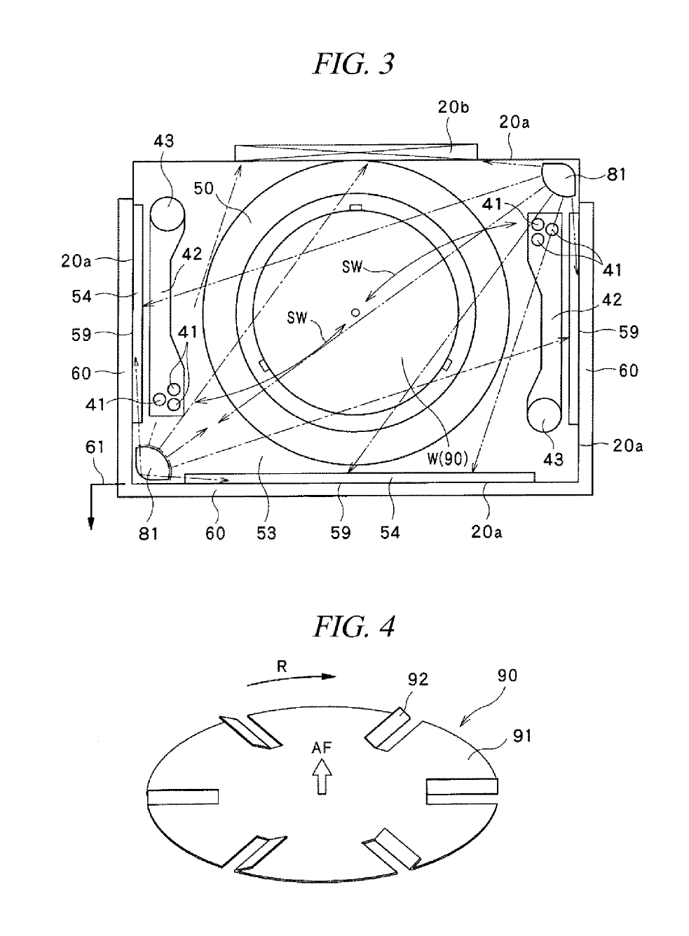

The processing fluid supply unit 40 has a plurality of (two in the shown example) nozzle arms 42. For the simplicity of illustration, only one of the two nozzle arms 42 is shown in FIG. 2. Some of the aforementioned nozzles 41 are provided to a leading end portion of each nozzle arm 42. The nozzle arm 42 is configured to be pivotable around the vertical axis line by an arm driving unit 43 (as indicated by an arrow SW in FIG. 3) and movable up and down in a vertical direction. By rotating the nozzle arm 42, the nozzles 41 provided at the nozzle arm 42 can be located at a certain position between a position above a central portion of the wafer W and a stand-by position (a home position shown in FIG. 3) at an outside of the liquid recovery cup 50, when viewed from the top.

Processing fluids (processing liquids or processing gases) are supplied to the respective nozzles 41 from corresponding processing fluid supply units (not shown). Though not shown, each processing fluid supply unit is equipped with a processing fluid supply source including a tank, a bomb, a factory power supply source, and so forth; a processing fluid line connecting the processing fluid supply source and the corresponding nozzle; and a flow control device such as a flow rate control valve or an opening/closing valve provided on the processing fluid line.

The liquid recovery cup 50 is disposed to surround the substrate holding unit 31 and is configured to collect the processing liquid scattered from the wafer W after supplied from the nozzle 41 onto the wafer W being rotated. A drain opening 51 is formed at a bottom portion of the liquid recovery cup 50, and the processing liquid collected by the liquid recovery cup 50 is drained to the outside of the processing unit 16 through the drain opening 51. Further, an exhaust opening 52 is formed at a bottom portion of the liquid recovery cup 50 to exhaust the gas supplied from the FFU 21 to the outside of the chamber 20 (processing unit 16).

A bottom plate (bottom wall) 53 is extended from an outer cylinder portion 50a of the liquid recovery cup 50 toward sidewalls 20a of the chamber 20. A surface of the bottom plate 53 is inclined to be lowered as it approaches the sidewalls 20a. Slit-shaped drain openings 54 are provided between the bottom plate 53 and the sidewalls 20a. As depicted in FIG. 3, the drain opening 54 is extended along three sidewalls 20a except the sidewall 20a where a wafer carry-in/out opening 20b with a shutter is provided. A drain channel 55 is provided under the drain opening 54, and the drain channel 55 is connected to a drain path 56.

The drain path 56 joins a drain path 57 connected to the drain opening 51 of the liquid recovery cup 50. The drain path 57 is provided with a switching valve device 58. By switching the switching valve device 58, a drained liquid flown through the drain paths 56 and 57 can be introduced into one of acidic, alkaline and organic factory draining systems (not shown).

Slit-shaped exhaust opening 59 extended in parallel with the aforementioned drain opening 54 is provided at the sidewalls 20a of the chamber 20 above the drain opening 54. Since the exhaust opening 59 is located at a higher position than the drain opening 54, the liquid is hardly introduced into the exhaust opening 59. The exhaust opening 59 is connected to a duct 60 which surrounds the sidewalls 20a of the chamber 20. The duct 60 is connected to an exhaust path 61 which is provided with an exhaust flow rate control valve 61a such as a butterfly valve or a damper.

The exhaust path 61 joins an exhaust path 62 connected to the exhaust opening 52 of the liquid recovery cup 50. The exhaust path 62 is provided with an exhaust flow rate control valve 62a such as a butterfly valve or a damper. The exhaust path 62 is provided with a switching valve device 63. By switching the switching valve device 63, an exhaust gas flown through the exhaust paths 61 and 62 can be introduced into one of acidic, alkaline and organic factory exhaust systems (not shown).

A plurality of, for example, two to four cleaning fluid nozzles 81 are disposed under the rectifying plate 26 within the chamber 20. It is desirable to locate the cleaning fluid nozzle 81 at a position as high as possible under the rectifying plate 26. The height position of the cleaning fluid nozzle 81 is higher than height positions of the nozzle 41 and the nozzle arms 42 (even when the nozzle 41 and the nozzle arm 42 are located at raised positions). As shown in FIG. 3, the cleaning fluid nozzles 81 are disposed at two corner portions of the rectangular chamber 20 when viewed from the top and arranged to face each other in a diagonal direction. The cleaning fluid nozzles 81 may be further disposed at the other two corners as well. Each cleaning fluid nozzle 81 is supported at an upper end portion of a supporting column 82 which is extended from the bottom plate 53 in a vertically upward direction. In FIG. 2, a lower end portion of the supporting column 82 is not shown for the simplicity of illustration.

Pure water as cleaning water from a cleaning water supply unit 83 and a solvent from a solvent supply unit 84 can be supplied into each of the cleaning fluid nozzles 81. The cleaning water supply unit 83 has a cleaning water supply path 83b which is connected to a cleaning water supply source 83c and provided with an opening/closing valve 83a. The solvent supply unit 84 has a solvent supply path 84b which is connected to a solvent supply source 84c and provided with an opening/closing valve 84a. By switching the opening/closing valves 83a and 84a, it is possible to discharge the pure water or the solvent selectively from the cleaning fluid nozzle 81. The cleaning fluid nozzles 81, the cleaning water supply unit 83 and the solvent supply unit 84 constitute a cleaning fluid discharging unit.

The solvent having higher volatility than the pure water and capable of replacing the pure water adhering to a surface of a member may be utilized. Desirably, isopropyl alcohol (IPA) may be used as the solvent. Since the IPA has surface tension much lower than that of water, the IPA is capable of replacing the pure water adhering to the surface of the member by using Marangoni effect. The IPA is an organic solvent which is most widely utilized in a drying process for drying a substrate such as a semiconductor wafer. Further, since the cleanness degree of the IPA when the IPA is discharged from the cleaning fluid nozzles 81 is not required to be as high as the cleanness degree required when the IPA is discharged toward the wafer W, it is possible to collect and reuse the IPA once supplied onto the wafer W. As the solvent, alternatively, acetone may be used.

The cleaning fluid nozzle 81 is configured to discharge the supplied liquid in the form of a mist at a relatively large angle (wide angle) at least with respect to a horizontal direction (see arrows assigned to the cleaning fluid nozzles 81 in FIG. 3). Since the mist of the liquid floats in the chamber and slowly falls down by gravity, a discharging angle of the cleaning fluid nozzles 81 in a vertical direction need not be as large (wide) as the discharging angle in the horizontal direction. By way of example, as indicated by arrows assigned to the cleaning fluid nozzles 81 in FIG. 2, the cleaning fluid nozzle 81 only needs to discharge the liquid mainly in the substantially horizontal direction (a part of the liquid may be discharged upwards or downwards in an inclined direction).

It is desirable to provide the cleaning fluid nozzles 81 such that a space under the rectifying plate 26 within the chamber 20 is completely filled with the mist of the liquid. The number and the arrangement of the cleaning fluid nozzles 81 are not limited to those of the shown example. Further, the cleaning fluid nozzles 81 may form the mist by using any one of a single-fluid mechanism or a two-fluid mechanism.

In FIG. 3, a cleaning jig 90 configured to accelerate the drying of a cleaning target, e.g., a member located in the vicinity of an upper portion of the substrate holding unit 31 of the substrate holding mechanism 30 is shown to be held by the substrate holding mechanism 30. As depicted in FIG. 4, the cleaning jig 90 includes a plate body 91 having the same diameter as the wafer W; and a multiple number of pins 92 provided on a top surface of the plate body 91. Since the shape and the size of the plate body 91 of the cleaning jig 90 is substantially the same as those of the wafer W, the cleaning jig 90 can be transferred by the substrate transfer devices 13 and 17. The pins 92 need to be configured to generate an air flow (as indicated by an arrow AF in FIG. 4) in the vicinity of the cleaning jig 90 when the cleaning jig 90 is rotated (as indicated by an arrow R in FIG. 4) while being held by the substrate holding mechanism 30.

The cleaning jig 90 may be rotated after the nozzle arm 42 is located above the cleaning jig 90 which is held by the substrate holding mechanism 30. At this time, to accelerate drying of a bottom surface of the nozzle arm 42, it may be desirable that the pins 92 are formed such that the air flow reaches the bottom surface of the nozzle arm 42 strongly. The air flow generated by the cleaning jig 90 may not be limited to an ascending air flow, but may be a swirling air flow, or the like.

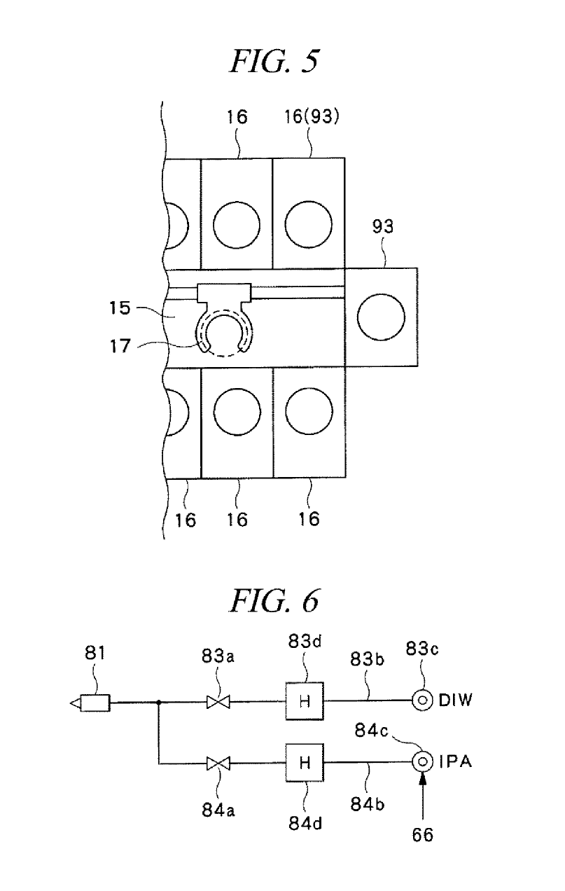

To place the cleaning jig 90, a jig accommodating unit 93 as a storage of the cleaning jig 90 may be provided within the transfer section 12 of the carry-in/out station 2 or within the processing station 3. By way of example, as schematically illustrated in FIG. 5, the jig accommodating unit 93 may be provided at a leading end position of the processing station 3 accessible by the substrate transfer device 17. Alternatively, the jig accommodating unit 93 may be accommodated in a place (indicated by a reference numeral 93, for example) where one of the processing units 16 is provided.

Now, an operation of the processing unit 16 will be discussed.

The wafer W is carried into the processing unit 16 by the substrate transfer device 17 and is held by the substrate holding mechanism 30. While rotating the wafer W about the vertical axis line by the substrate holding mechanism 30, one of the nozzle arms 42 locates the nozzle 41, which is required for the process involved, above the wafer W, and the processing fluid (processing liquid or processing gas) is supplied to the wafer W.

By way of example, a chemical liquid process of supplying a chemical liquid (e.g., DHF, BHF, SC-1, SPM, etc.) onto the wafer W through the chemical liquid nozzle 41a is first performed. Then, a rinsing process of supplying pure water (DIW) as a rinse liquid onto the wafer W through the rinse nozzle 41b is performed. Subsequently, a solvent replacing process of supplying a drying solvent (here, IPA) onto the wafer W through the solvent nozzle 41c is conducted. Thereafter, a drying process of drying the wafer W by spinning the wafer W at a high speed is performed. After the completion of the drying process, the processed wafer W is carried out of the processing unit 16 by the substrate transfer device 17.

Clean air is being supplied into the chamber 20 from the FFU 21 at a preset flow rate FL1 while the wafer is being carried into/out of the chamber 20 and while the chemical liquid process, the rinse process, the solvent replacing process are being performed. Further, an atmosphere within the liquid recovery cup 50 is exhausted through the exhaust opening 52 of the liquid recovery cup 50 at a predetermined flow rate FL2. Furthermore, an atmosphere within the chamber 20 is also exhausted through the exhaust opening 59 formed at the sidewalls 20a of the chamber 20 at a preset flow rate FL3.

While the drying process is being performed, the supply of the clean air from the FFU 21 into the chamber 20 is stopped, and dry air is supplied into the space 27 above the rectifying plate 26 from the low-humidity gas supply unit 28 at the aforementioned preset flow rate FL1. The flow rate of the exhaust gas having passed through the exhaust opening 52 and the flow rate of the exhaust gas having passed through the exhaust openings 59 are maintained at the aforementioned flow rates FL2 and FL3, respectively.

While the drying process is being performed, the IPA scattered from the wafer W after being supplied onto the wafer W and collected by the liquid recovery cup 50 may be used again in the solvent supplying process for cleaning of the inside of the chamber 20 to be described later. To this end, a collection tank 65 configured to collect the IPA drained out from the drain path 57 which is connected to the drain opening 51 of the liquid recovery cup 50 may be provided. By switching the opening/closing valves 67a and 67b, it is possible to switch a state in which the IPA collected into the collection tank 65 is returned back into the solvent supply source 84c of the solvent supply unit 84 through an IPA supply path 66 and a state in which the collected IPA is just wasted without being returned back. While the drying process is being performed, the switching valve device 58 connects the drain path 57 to the collection tank 65.

While the chemical liquid process is being performed, most of the chemical liquid supplied onto the wafer W is collected by the liquid recovery cup 50. However, some of the chemical liquid that is turned into mist by collision with the wafer W or the like may be scattered over the liquid recovery cup 50. This scattered mist of the chemical liquid adheres to the sidewall 20a of the chamber 20, a surface of the bottom plate 53 and surfaces of devices within the chamber 20 such as the nozzle arm 42 (particularly, bottom surface of the nozzle arm 42). The chemical liquid adhering thereto may turn the atmosphere within the chamber 20 into an undesirable atmosphere (for example, acidic or alkaline atmosphere). Further, if the chemical liquid attached to the aforementioned various surfaces is solidified and peeled off from the surfaces, it may cause particle generation. For this reason, the cleaning of the inside of the chamber 20 is performed whenever the processing of a single sheet of wafer W is completed or is performed periodically (for example, whenever the processing of a preset number of, e.g., 20 sheets of wafers W is completed or whenever the processing unit 16 is operated for a predetermined time period), or whenever the degree of contamination within the chamber 20 reaches a preset level.

A cleaning method of cleaning the inside of the chamber 20 will now be explained. Cleaning of the inside of the liquid recovery cup 50 may be performed at the same time as or at the different time from the cleaning of the inside of the chamber 20. In the present exemplary embodiment, the cleaning of the inside of the liquid recovery cup 50 is not described. The cleaning method of cleaning the inside of the chamber 20 is automatically performed as the control device 4 controls various devices of the processing unit 16 based on a cleaning recipe stored in the storage unit 19.

[In-Chamber Cleaning Process (Cleaning Process)]

First, mist of DIW as a cleaning liquid is discharged into the chamber 20 from the cleaning fluid nozzles 81. This discharge of the DIW is continuously performed for a preset time period, and then stopped. At this time, the clean air is also supplied into the chamber 20 from the FFU 21 at the aforementioned flow rate FL1. Further, the flow rate of the exhaust gas having passed through the exhaust opening 52 of the liquid recovery cup 50 and the flow rate of the exhaust gas having passed through the exhaust opening 59 of the sidewalls 20a of the chamber 20 are set to the aforementioned flow rates FL2 and FL3, respectively. If the internal space of the chamber 20 is filled with the mist of the DIW, the mist of the DIW adheres to a wall (e.g., sidewall 20a and bottom plate 53) facing the internal space of the chamber 20 and a surface of a member (hereinafter, referred to as “cleaning target”) such as a device (e.g., nozzle arm 42) within the chamber 20. By filling the internal space of the chamber 20 with the mist of the DIW, the mist of the DIW can be attached to a downward surface such as the bottom surface of the nozzle arm 42.

By maintaining a state where the surface of the cleaning target within the chamber 20 is wet with the DIW, the chemical liquid adhering to the surface of the cleaning target and the solid originated from the chemical liquid are dissolved by the DIW. The DIW is capable of dissolving most of substances that can be attached to the surface of the cleaning target. The DIW attached to the bottom plate 53 is flown along the inclination of the bottom plate 53 to be introduced into the drain opening 54. The DIW attached to the sidewalls 20a falls down by gravity to be introduced into the drain opening 54 directly or via the inclined surface of the bottom plate 53. The DIW attached to the nozzle arm 42 is introduced into the drain opening 51 after falling down into the liquid recovery cup 50, or introduced into the drain opening 54 along the inclined surface of the bottom plate 53 after falling down onto an outer surface of the liquid recovery cup 50 or onto the surface of the bottom plate 53. That is, most of the DIW discharged from the cleaning fluid nozzles 81 is drained from the processing unit 16 through the drain opening 51 of the liquid recovery cup 50 or the drain opening 54 of the bottom plate 53.

While the in-chamber cleaning process is being performed, for example, in a later stage of the in-chamber cleaning process, the DIW adhering to the substrate holding unit 31 may be removed by rotating the substrate holding unit 31 of the substrate holding mechanism 30.

[In-Chamber Solvent Supplying Process (Solvent Supplying Process)]

After the discharge of the DIW from the cleaning fluid nozzles 81 is stopped, the DIW remains adhering to the sidewalls 20a, the bottom plate 53 and the surface of the device within the chamber 20 such as the nozzle arm 42. To accelerate drying of this DIW, an in-chamber solvent supplying process of supplying a solvent into the chamber is performed. Prior to performing this in-chamber solvent supplying process, the wafer carry-in/out opening 20b is opened, and the cleaning jig 90 is carried into the chamber 20 to be held by the substrate holding unit 31.

Subsequently, mist of IPA is discharged from the cleaning fluid nozzles 81, and, accordingly, the IPA is supplied toward the DIW adhering to the surface of the cleaning target. This discharge of the mist of the IPA is continuously performed for a predetermined time period, and then stopped. When performing the in-chamber solvent supplying process, conditions for the supply of the clean air from the FFU 21, the gas exhaust through the exhaust opening 52 of the liquid recovery cup 50 and the gas exhaust through the exhaust openings 59 of the sidewalls 20a of the chamber 20 may be set to be the same as the conditions when performing the in-chamber cleaning process. Here, however, the exhaust gases are sent to the organic factory exhaust system.

A recovery path of the IPA which is discharged in the in-chamber solvent supplying process is the same as a recovery path of the DIW which is discharged in the in-chamber cleaning process. Here, the collected IPA is sent into the organic factory draining system, whereas the collected DIW is sent into the acidic or alkaline factory draining system.

If the discharged IPA reaches the DIW adhering to the surface of the cleaning target, the DIW is pushed away by the IPA, so that at least most of the DIW adhering to the surface of the cleaning target is replaced by the IPA. After the discharge of the IPA from the cleaning fluid nozzles 81 is stopped, the IPA remains adhering to the surface of the cleaning target.

[In-Chamber Drying Process (Drying Process)]

The IPA attached to the surface of the cleaning target can be dried naturally. Since volatility of the IPA is much higher than that of the DIW, the IPA attached to the surface of the cleaning target can be dried in a short period of time.

After or slightly before the discharge of the IPA from the cleaning fluid nozzles 81 is stopped, the supply of the clean air (humidity of this clean air is the same as that of the air in the clean room) from the FFU 21 is stopped, and, instead, the dry air is supplied into the chamber 20 through the space 27 above the rectifying plate 26 from the low-humidity gas supply unit 28. As a result, the humidity within the chamber 20 is reduced, so that the drying of the cleaning target can be accelerated. Furthermore, when performing this in-chamber drying process, conditions for the gas exhaust through the exhaust opening 52 of the liquid recovery cup 50 and the gas exhaust through the exhaust openings 59 of the sidewalls 20a of the chamber 20 may be maintained the same as the conditions for the in-chamber solvent supplying process.

A mass of the DIW pushed away by the IPA or a mass of the IPA may be attached to the bottom surface of the nozzle arm 42. If this mass of the liquid remains, the drying thereof is delayed. To remove this mass of the liquid, the nozzle arm 42 is rotated to be located above the cleaning jig 90, and the cleaning jig 90 is rotated. As a result, an air flow is generated in the vicinity of the cleaning jig 90 and in a space above the cleaning jig 90, and the mass of the liquid adhering to the bottom surface of the nozzle arm 42 is blown way, so that the drying of the nozzle arm 42 can be accelerated. Furthermore, even in case that the mass of the liquid is not attached to the bottom surface of the nozzle arm 42 and the bottom surface of the nozzle arm 42 is just wet with the liquid, the drying of the nozzle arm 42 is still accelerated by the air flow.

If the surface of the cleaning target is dried, the cleaning jig 90 is taken out of the processing unit 16 by the substrate transfer device 17 and is placed again in the jig accommodating unit 93. Then, immediately afterwards, a wafer W may be carried into the processing unit 16 and the processing of the wafer W may be started.

According to the above-described exemplary embodiment, the surface of the cleaning target within the chamber 20 is cleaned with the DIW, and, then, the DIW is replaced by the solvent having high volatility. Accordingly, the surface of the cleaning target can be dried rapidly. Thus, the downtime of the processing unit 16 can be shortened greatly, so that the substrate processing system 1 can be operated efficiently.

Further, the above-described exemplary embodiment may be modified as follows.

In the above-described exemplary embodiment, the DIW and the IPA are discharged from the same nozzles 81. However, they may be discharged from different nozzles.

The cleaning jig 90 may be carried into the chamber 20 and held by the substrate holding unit 31 before the in-chamber cleaning process is begun. In this case, when performing the in-chamber cleaning process, the nozzle arm 42 is rotated to be located above the cleaning jig 90 and the cleaning jig 90 is rotated. Then, the mist of the DIW flows toward the bottom surface of the nozzle arm 42 along the air flow created by the cleaning jig 90. Therefore, the bottom surface of the nozzle arm 42 that might be easily contaminated by the splash of the chemical liquid can be cleaned more securely.

If the cleaning jig 90 is carried into the chamber 20 after the in-chamber cleaning process and before the in-chamber solvent supplying process, the DIW adhering to, e.g., the rectifying plate 26 may fall down as liquid droplets, and the arm of the substrate transfer device 17 may be wet. However, by carrying the cleaning jig 90 into the chamber 20 before the in-chamber cleaning process is started, such a problem can be avoided.

The cleaning jig 90 may also be rotated while the in-chamber solvent supplying process is being performed. If so, the mist of the IPA can be more easily attached to a place where it has been difficult for the mist of the IPA to adhere, so that the replacement efficiency can be improved.

In the in-chamber solvent supplying process, it may be possible to discharge heated IPA from the cleaning fluid nozzles 81. By supplying the heated IPA, the drying process can be completed in a shorter period of time. For this purpose, a heater 84d may be provided on the solvent supply path 84b of the solvent supply unit 84, as schematically illustrated in FIG. 6. Alternatively, the heater 84d may be provided in a tank (not shown) serving as the solvent supply source 84c.

In the in-chamber cleaning process, it may be possible to discharge heated DIW from the cleaning fluid nozzles 81 to heat the cleaning target. By supplying the heated DIW, the drying process can be completed in a shorter period of time. To this end, a heater 83d may be provided on the cleaning water supply path 83b of the cleaning water supply unit 83, as schematically illustrated in FIG. 6. Alternatively, the heater 83d may be provided in a tank (not shown) serving as the cleaning water supply source 83c. By supplying the heated DIW, the target substances to be removed can be dissolved more efficiently.

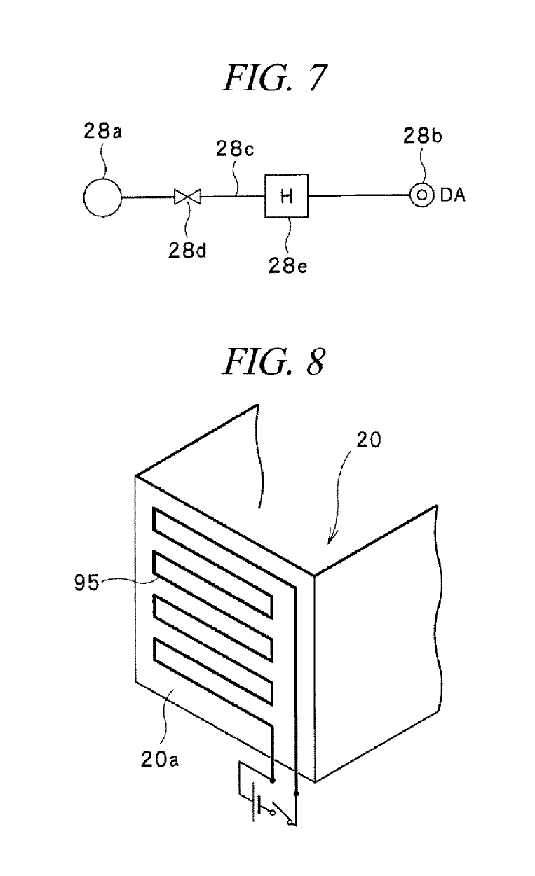

In the in-chamber drying process, it may be possible to supply heated dry air from the low-humidity gas supply unit 28. By supplying the heated dry air, the in-chamber drying process can be completed in a shorter period of time. For this purpose, a heater 28e may be provided on the gas supply path 28c of the low-humidity gas supply unit 28, as schematically illustrated in FIG. 7.

In the in-chamber cleaning process or in the in-chamber solvent supplying process, the flow rate of the exhaust gas having passed through the exhaust opening 52 of the liquid recovery cup 50 and the flow rate of the exhaust gas having passed through the exhaust opening 59 of the sidewalls 20a of the chamber 20 may be varied while maintaining a sum of the two flow rates at a value of FL2+FL3. Through this, it is possible to change the air flow within the chamber 20 while maintaining the internal pressure of the chamber 20 substantially constant. In this case, it may be possible to allow the mist to be easily attached to a portion of the cleaning target where it has been difficult for the mist to adhere.

In the in-chamber cleaning process or in the in-chamber solvent supplying process, a rotational speed of the cleaning jig 90 may be varied (including the rotational speed set to be zero) to change the air flow within the chamber 20. Further, in the in-chamber cleaning process or in the in-chamber solvent supplying process, a movable member within the chamber 20 may be moved. By way of example, by rotating the nozzle arm 42 or moving it up and down, adhesion of the mist to the entire nozzle arm 42 can be accelerated.

The surface of the wall (e.g., sidewall 20, bottom plate 53, etc.) within the chamber 20 may be formed of a hydrophilic material. Further, a hydrophilic thin film may be formed on the surface of the wall or a hydrophilic treatment may be performed on the surface of the wall. Since a contact angle of a liquid with respect to the hydrophilic surface is small, the IPA having the low surface tension can be more easily diffused on the surface of the wall, so that the evaporation of the IPA can be accelerated. Besides the walls, the surface of the cleaning target may also be made hydrophilic.

As schematically depicted in FIG. 8, a heater 95 may be provided to the wall (side wall 20a, bottom plate 53, or the like) of the chamber 20. By way of non-limiting example, the heater 95 may be implemented by one similar to a printed heating wire for removing a condensation on a glass of a car. By heating the wall, the evaporation of the IPA can be accelerated.

The substrate as the processing target object in the substrate processing apparatus is not limited to the semiconductor wafer, and various other kinds of substrates, such as a glass substrate and a ceramic substrate, may be used.

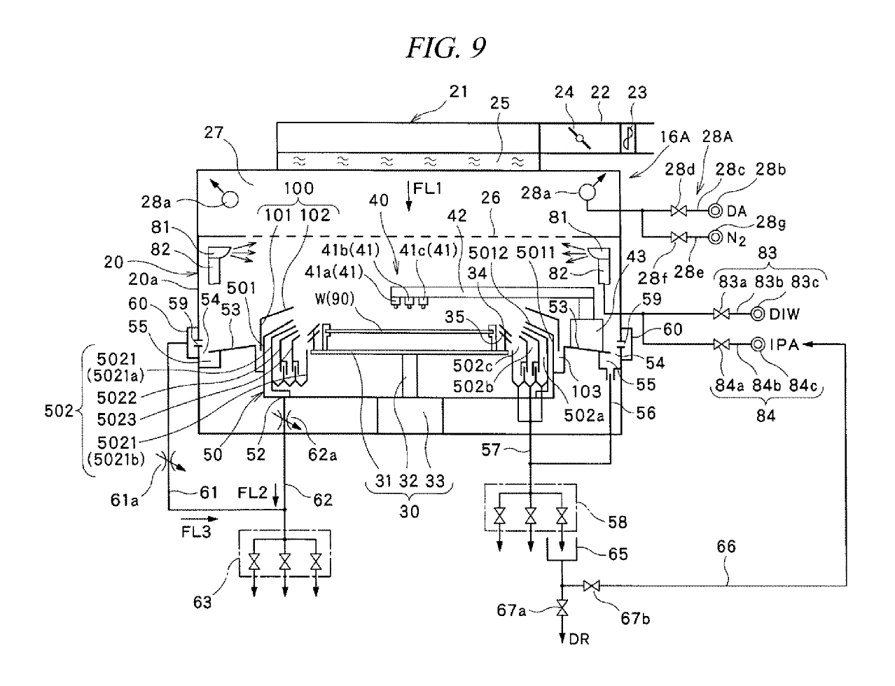

Now, a processing unit (referred to as “processing unit 16A” for distinction) according to another exemplary embodiment (hereinafter, referred to as “second exemplary embodiment”) will be explained with reference to FIG. 9 to FIG. 11. Further, the exemplary embodiment described so far will be referred to as “first exemplary embodiment” for the convenience of explanation. In FIG. 9 to FIG. 11 illustrating the second exemplary embodiment, same components as those described in the first exemplary embodiment will be assigned same reference numerals, and redundant description thereof will be omitted.

In the processing unit 16A according to the second exemplary embodiment, the liquid recovery cup 50 includes a stationary (fixed) exhaust cup 501 at an outermost position; and a drain cup 502 for guiding a processing liquid, which is located inside the exhaust cup 501.

The drain cup 502 includes a drain cup main body 5021; and a first movable cup element 5022 and second movable cup element 5023 each configured to be movable up and down by a non-illustrated elevating device. Further, a ring-shaped first rotary cup 34 and a ring-shaped second rotary cup 35 are provided at the substrate holding unit 31 to be rotated along with the substrate holding unit 31. By changing positions of the first movable cup element 5022 and the second movable cup element 5023 in a vertical direction, an inlet of any one of a first drain passageway 502a for an organic liquid between an outer peripheral portion 5021a of the drain cup main body 5021 and the first movable cup element 5022, a second drain passageway 502b for an acidic liquid between the first movable cup element 5022 and the second movable cup element 5023 and a third drain passageway 502c for an alkaline liquid between the second movable cup element 5023 and an inner peripheral portion 5021b of the drain cup main body 5021 can be opened. The processing liquid scattered outwards through a minute gap between the first rotary cup 34 and the second rotary cup 35 after dispersed from the wafer W is introduced into the drain passageway (one of the drain passageways 502a to 502c) the inlet of which is opened. Drain paths are connected to bottom portions of the drain passageways, respectively, and these drain paths converge into the drain path 57, and then, joins the drain path 56.

The exhaust cup 501 includes an outer cylindrical portion 5011 and a protruding portion 5012 protruded inwardly from an upper end portion of the outer cylindrical portion 5011 in a radial direction thereof. An exhaust passageway 501a is formed between the exhaust cup 501 and the outer peripheral portion 5021a of the drain cup main body 5021. The exhaust opening 52 is formed at a bottom portion of the exhaust passageway 501a, and an exhaust duct (exhaust path) 62 is connected to the exhaust opening 52. The first rotary cup 34 is configured to suppress the processing liquid scattered from the wafer W being rotated from being introduced into the inside of the exhaust passageway 501a directly.

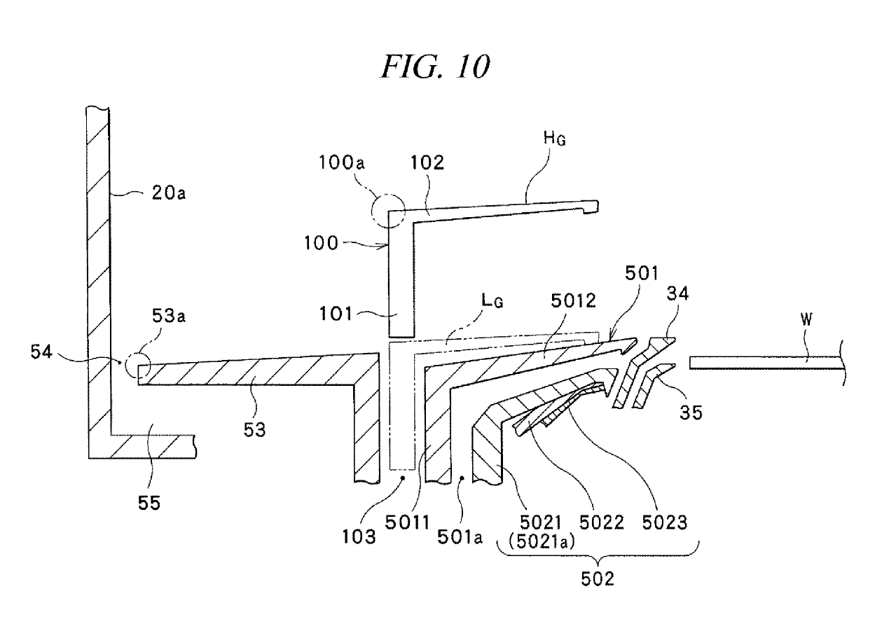

In order to prevent or at least to suppress to the great extent the processing liquid dispersed from the wafer W being rotated, particularly, the processing liquid in the form of fine mist from reaching the sidewalls 20a of the chamber 20, a mist guard 100 is provided at an outside of the liquid recovery cup 50 (i.e., at an outside of the exhaust cup 501). The mist guard 100 includes an outer cylindrical portion 101; and a protruding portion 102 extended from an upper end portion of the outer cylindrical portion 101 toward the inside of the outer cylindrical portion 101 (i.e., inwardly in the radial direction) and protruded above the exhaust cup 501. The mist guard 100 is moved up and down by a non-illustrated elevating device to be located at a high position H_{G} and a low position L_{G} (see FIG. 10).

A cylindrical guard pocket 103 (mist guard accommodating space) for accommodating the outer cylindrical portion 101 of the mist guard 100 is formed at an outside of the outer cylindrical portion 5011 of the exhaust cup 501. The bottom plate 53 is extended outwards from the guard pocket 103.

A low-humidity gas supply unit (referred to as “low-humidity gas supply unit 28A” for distinction) according to the second exemplary embodiment is configured to selectively supply either a nitrogen gas as a gas having a low humidity and a low oxygen concentration or a dry air as a low-humidity gas. At a downstream side of the flow control device 28d (e.g., opening/closing valve), another gas supply path 28e joins the gas supply path 28c. The gas supply path 28e is equipped with a flow control device 28f (e.g., opening/closing valve). A dry air supply source 28b is connected to the gas supply path 28c, and a nitrogen gas supply source 28g is connected to the gas supply path 28e. By switching the flow control devices 28d and 28f, it is possible to supply either one of the dry air and the nitrogen gas to the nozzle 28a.

A blast treatment is performed on members exposed to an atmosphere within the chamber 20, particularly, inner surfaces of the sidewalls 20a of the chamber 20, a top surface of the bottom plate 53, a top surface of the protruding portion 102 of the mist guard 100, an entire surface of the nozzle arm 42, an entire surface of the arm driving unit (supporting column and driving device accommodating portion). As well known in the art, if the blast treatment is performed on a surface of a member, fine irregularity is formed on the surface of the member, so that the surface becomes hydrophilic. Thus, by performing the blast treatment on each of the aforementioned surfaces and thus hydrophilizing them, a liquid (liquid droplet) adhering to those surfaces can be diffused in a wide range to be easily evaporated.

Although it is desirable to perform the blast treatment on as many portions as possible to which the liquid droplet discharged from the cleaning fluid nozzles 81 is attachable, that is, as many portions as possible on surfaces of the bottom plate 53 and members located above it, the blast treatment may be performed only on a portion where a delay of the drying causes a problem (that is, only on a part of the surfaces of the bottom plate 53 and the members located above it).

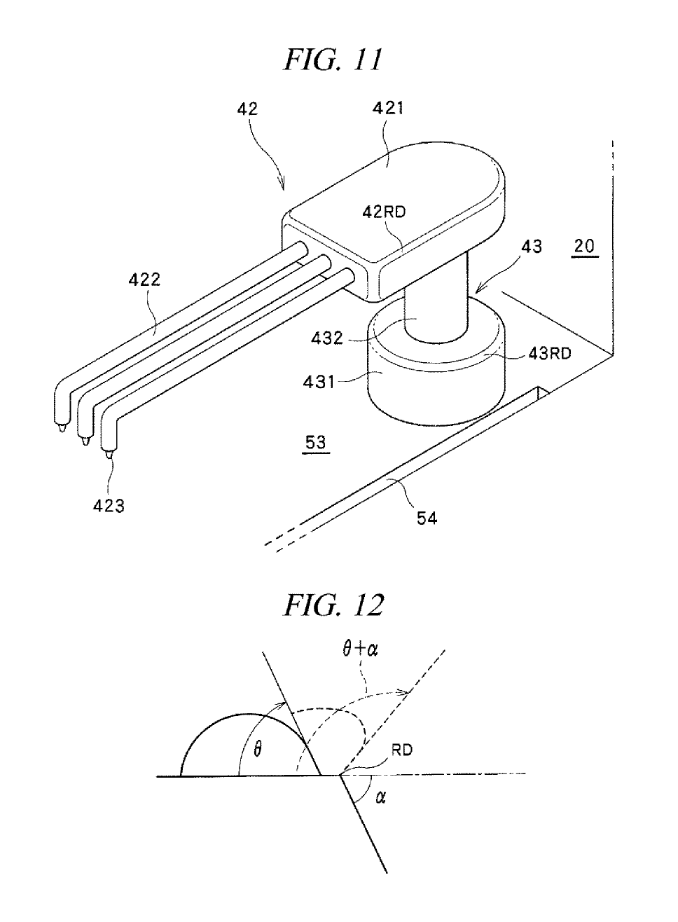

As depicted in FIG. 12, there is known “pining effect of wetting” which refers to a phenomenon that if two solid surfaces intersect with each other at an angled corner (corner portion) (indicated by RD) at a bending angle a when an equilibrium contact angle on the solid surface is θ, a liquid droplet that has flown toward the corner do not flow ahead of the corner until the contact angle at the corner exceeds θ+α. If the liquid droplet stay at the corner due to the pinning effect of wetting, it takes a long time for the liquid droplet to evaporate, so that the drying of the inside of the chamber 20 may be delayed. Examples of such a place where the problem of stay of the liquid droplet caused by the pinning effect of wetting may occur is a corner (a portion 100a surrounded by a dashed dotted line in FIG. 10) where the outer cylindrical portion 101 and the protruding portion 102 of the mist guard 100 intersect, a corner (edge) (a portion 53a surrounded by a dashed dotted line in FIG. 10) of the bottom plate 53 facing the drain opening 54, and so forth. Since these corners are located at lower ends of inclined surfaces, liquid droplets may easily gather thereat. Further, as another examples of the place where the stay of the liquid droplet caused by the pinning effect of wetting may cause a problem, there may be a corner portion that exist at the nozzle arm 42, a corner portion that exists at the arm driving unit 43, and so forth (see FIG. 11). In this second exemplary embodiment, by performing R chamfering on the aforementioned corner portions, the pinning effect of wetting is suppressed.

Furthermore, in the configuration shown in FIG. 9 and FIG. 10, if the mist guard 100 is omitted, it may be considered to perform R chamfering on a portion where an outermost constituent element and an uppermost constituent element of the liquid recovery cup 50, that is, where the outer cylindrical portion 5011 and the protruding portion 5012 of the exhaust cup 501 intersect with each other.

Though it is desirable to perform R chamfering on as many corners (corner portions) as possible where the liquid droplet discharged from the cleaning fluid nozzles 81 may flow and stay, the R chamfering may be performed only on the portions where the delay of drying may cause the problem.

A radius of curvature of R chamfering for suppressing the pinning effect of wetting effectively is equal to or larger than 2 mm. This radius of curvature equal to or larger than 2 mm is much bigger than a radius of curvature of chamfering conducted to remove a burr of mechanical machining or chamfering for rounding a sharp edge for the sake of operator's safety.

FIG. 11 illustrates examples of the nozzle arm 42 and the arm driving unit 43 on which the blast treatment and the R chamfering process are performed. This nozzle arm 42 includes a base portion 421 and rod-shaped portions 422. A base end portion of each of the rod-shaped portions 422 is fixed to the base portion 421. A leading end portion of each rod-shaped portion 422 is bent downward at about 90 degrees, and a nozzle 423 (corresponding to the nozzle 41 in the schematic diagram of FIG. 9) is provided at a lower end portion of this downwardly extended portion of each rod-shaped portion 422. Provided within each rod-shaped portion 422 is a non-illustrated processing liquid flow path which is extended in an axial direction of each rod-shaped portion 422 and through which a processing liquid is supplied into the nozzle 423.

The arm driving unit 43 has a substantially cylindrical base portion 431 and a substantially cylindrical shaft unit 432. The base portion 431 is inserted into a hole formed in the bottom plate 53 and is fastened to a non-illustrated frame of the processing unit 16A under the bottom plate 53. The shaft unit 432 is configured to be movable up and down and pivotable around the vertical axis line by a non-illustrated actuator embedded in the base portion 431.

The R chamfering is performed on a corner portion 42RD where a side surface and a top surface of the base portion 421 of the nozzle arm 42 meet. The R chamfering may also be performed on a corner portion where side surfaces meet. Each of the rod-shaped portion 422 of the nozzle arm 42 is of the cylindrical shape and hardly has a corner portion. The R chamfering is also performed on a corner portion 43RD where a side peripheral surface and a top surface of the cylindrical base portion 431 of the arm driving unit 43 meet. By forming these R chamfers (having a radius of curvature equal to or larger than 2 mm), it is possible to suppress the pinning effect of wetting on the corner or the corner portions.

The blast treatment is performed on a part of the surfaces of the base portion 421 of the nozzle arm 42, for example, the top surface thereof or, desirably, the entire surface of the base portion 421. Further, the blast treatment is also performed on at least a part of a surface of the rod-shaped portion 422 of the nozzle arm 42, desirably, the entire surface of the rod-shaped portion 422. Furthermore, the blast treatment is also performed on at least a part of the side peripheral surface and the top surface of the cylindrical base portion 431 of the arm driving unit 43, desirably, the entire surface of the base portion 431. Accordingly, the liquid (e.g., IPA) adhering to the surfaces on which the blast treatment has been performed is diffused and easily evaporated.

Now, an operation of the processing unit 16A according to the second exemplary embodiment will be explained.

Processes (chemical liquid process, rinse process, solvent replacing process and drying process) performed on the wafer W in this second exemplary embodiment are almost the same as those performed on the wafer W in the first exemplary embodiment except the following. In the following, only distinctive features will be explained. First, depending on the processing liquid (acidic chemical liquid, alkaline chemical liquid, pure water, organic solvent) that is used, the height positions of the first movable cup element 5022 and the second movable cup element 5023 are adjusted, and the draining of the liquid is performed through the drain passageway of the drain cup 502 (one of the first drain passageway 502a for the organic liquid, the second drain passageway 502b for the acidic liquid and the third drain passageway 502c for the alkaline liquid) corresponding to the processing liquid that is used. Further, in the chemical liquid process, the rinse process and the solvent replacing process, by locating the mist guard 100 at the high position H_{G}, the processing liquid scattered from the wafer W being rotated is suppressed from reaching the sidewalls 20a of the chamber 20. The mist guard 100 is located at the low position L_{G} when the drying process is performed.

Processes (in-chamber cleaning process, in-chamber solvent supplying process and in-chamber drying process) constituting a cleaning method of cleaning the inside of the chamber according to the second exemplary embodiment are substantially the same as those of the cleaning method of cleaning the inside of the chamber 20 according to the first exemplary embodiment. Only distinctive features will be described below.

Throughout the entire processes of the in-chamber cleaning process, the in-chamber solvent supplying process and the in-chamber drying process, the mist guard 100 is located at the low position L_{G}. If the mist guard 100 is raised to be located at the high position H_{G}, the mist of the DIW and the IPA discharged from the cleaning fluid nozzles 81 may not be diffused into the chamber 20.

When the in-chamber cleaning process is performed, by setting the height positions of the first movable cup element 5022 and the second movable cup element 5023 appropriately, the second drain passageway 502b for the acidic liquid or the third drain passageway 502c for the alkaline liquid is opened, and the cleaning liquid (DIW) from the cleaning liquid nozzles 81 which is introduced into the drain dup 502 through the opened drain passageway is drained out. In this in-chamber cleaning process, if the inside of the chamber 20 is in a low-humidity atmosphere, there may be a likelihood that the cleaning liquid may be evaporated and not diffused within the chamber 20. Thus, as in the first exemplary embodiment, the clean air (not having a low humidity) is supplied into the chamber 20 from the FFU 21.

When the in-chamber solvent supplying process is performed, by setting the height positions of the first movable cup element 5022 and the second movable cup element 5023 appropriately, the first drain passageway 502a for the organic liquid is opened, and the IPA from the cleaning fluid nozzles 81 which is introduced into the drain cup 502 through the first drain passageway 502a is drained out. The drained IPA may be collected into the collection tank 65, and the collected IPA may be sent to the solvent supply source 84c of the solvent supply unit 84 through the IPA supply path 66 to be reused. When this in-chamber solvent supplying process is performed and when the in-chamber drying process is performed, the supply of the clean air from the FFU 21 is stopped, and a nitrogen gas is supplied into the chamber 20 from the low-humidity gas supply unit 28A via the nozzle 28a. If the inside of the chamber 20 is in an oxygen atmosphere, an oxygen-originated spot may be generated within the chamber 20. Thus, by supplying the nitrogen gas into the chamber 20, an oxygen concentration within the chamber 20 is controlled to be lowered.

Further, since the nitrogen gas is more expensive than the dry air, the dry air is used as the low-humidity gas supplied from the low-humidity gas supply unit 28A when the liquid process is performed on the wafer W, as in the first exemplary embodiment.

In the above-described second exemplary embodiment, the blast treatment is performed on the surfaces of the members to which the liquid droplet discharged from the cleaning liquid nozzle 81 adheres. In general, since most of in-chamber members are made of a polymer material which is not highly hydrophilic, it is difficult for the liquid droplet to be diffused, and it takes time for the liquid to be evaporated (dried). However, by performing the blast treatment on the surfaces of these members, the surfaces of the members become hydrophilic, and the liquid can be diffused easily. Therefore, a time required for evaporating the liquid can be shortened. That is, the mist of the IPA supplied in the in-chamber solvent supplying process can be evaporated in a short period of time during the in-chamber drying process. As a result, a time required to complete the cleaning method of cleaning the inside of the chamber can be shortened, so that the downtime of the processing unit 16A can be shortened.

Moreover, in the second exemplary embodiment, since the R chamfers having a radius of curvature equal to or larger than 2 mm are formed on the corners (corner portions, edges), the liquid (mist of the IPA from the cleaning fluid nozzles 81) can be suppressed from staying at the corners as the liquid droplet caused by the pinning effect of wetting. Therefore, the mist of the IPA supplied in the in-chamber solvent supplying process can be evaporated in a short period of time during the in-chamber drying process, so that the time required to complete the cleaning method of cleaning the inside of the chamber can be further shortened. Further, in the first exemplary embodiment and the second exemplary embodiment, a hygrometer may be provided in the chamber and the humidity within the chamber may be detected. In the in-chamber drying process, if a detection value of the humidity within the chamber is equal to or less than a preset value, it is possible to determine that an amount of the pure water as the cleaning water remaining in the chamber reaches an amount that does not affect the process performed on the wafer W, or it is possible to determine that the pure water in the chamber is removed so that the in-chamber drying process is completed. Accordingly, it is possible to determine that the process on the wafer W may be started. Further, in the in-chamber solvent supplying process, if the detection value of the humidity within the chamber is equal to or less than a preset value, it is possible to determine that the pure water as the cleaning water remaining in the chamber is replaced with the IPA so that the supply of the IPA may be stopped.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting.

We claim:

1. A substrate processing apparatus, comprising:
a processing chamber;
a substrate holding unit provided within the processing chamber and configured to hold a substrate;
a processing liquid nozzle configured to supply a processing liquid onto the substrate held by the substrate holding unit; and
a cleaning fluid discharging unit configured to discharge water for cleaning a cleaning target within the processing chamber and a solvent having higher volatility than the water into an internal space of the processing chamber.

2. The substrate processing apparatus of claim 1,
wherein the cleaning fluid discharging unit is configured to discharge the water in a form of mist and discharge the solvent in a form of mist.

3. The substrate processing apparatus of claim 1,
wherein the cleaning fluid discharging unit includes a cleaning fluid nozzle,
a cleaning water supply unit and a solvent supply unit are connected to the cleaning fluid nozzle, and
either one of the water and the solvent is discharged from the cleaning fluid nozzle independently.

4. The substrate processing apparatus of claim 1,
wherein the cleaning fluid discharging unit includes a heater configured to heat the solvent.

5. The substrate processing apparatus of claim 1, further comprising:
a low-humidity gas supply unit configured to selectively supply dry air or a nitrogen gas as a low-humidity gas into the processing chamber; and
a control unit configured to control the low-humidity gas supply unit to supply the dry air into the processing chamber when the substrate held by the substrate holding unit is processed within the processing chamber, and to supply the nitrogen gas into the processing chamber when the cleaning target within the processing chamber is cleaned.

6. The substrate processing apparatus of claim 5,
wherein the low-humidity gas supply unit includes a heater configured to heat the nitrogen gas.

7. The substrate processing apparatus of claim 1, further comprising:
a rotation driving unit configured to rotate the substrate holding unit;
a transfer device configured to transfer a cleaning jig onto the substrate holding unit; and
a control unit configured to rotate the substrate holding unit by operating the rotation driving unit,
wherein the cleaning jig is allowed to be held by the substrate holding unit, and
by rotating the cleaning jig held by the substrate holding unit after the discharge of the solvent from the cleaning fluid discharging unit is completed, an air flow for accelerating drying of the cleaning target to which the solvent or the water adheres is generated in the vicinity of the cleaning jig.

8. The substrate processing apparatus of claim 7, further comprising:
a processing fluid nozzle configured to discharge a processing fluid onto the substrate held by the substrate holding unit;
a nozzle arm configured to hold the processing fluid nozzle; and
an arm driving unit configured to move the nozzle arm,
wherein the processing fluid nozzle, the nozzle arm and the arm driving unit are provided within the processing chamber,
the control unit is configured to control the arm driving unit to locate the nozzle arm above the cleaning jig being rotated after the discharge of the solvent from the cleaning fluid discharging unit is completed, and drying of a bottom surface of the nozzle arm to which the solvent or the water adheres is accelerated by the air flow generated by the cleaning jig.

9. The substrate processing apparatus of claim 1, further comprising:
a heater configured to heat a wall of the processing chamber.

10. The substrate processing apparatus of claim 1,
wherein a height position of the cleaning fluid discharging unit is higher than a height position of the processing liquid nozzle.

11. The substrate processing apparatus of claim 1,
wherein the cleaning target includes a sidewall of the processing chamber facing the internal space of the processing chamber.

12. The substrate processing apparatus of claim 1,
wherein a blast treatment is performed on a surface of the cleaning target where the solvent discharged from the cleaning fluid discharging unit is allowed to adhere.

13. The substrate processing apparatus of claim 1,
wherein R chamfering having a radius of curvature equal to or larger than 2 mm is performed on a corner where an upwardly facing surface of a member within the processing chamber where the solvent discharged from the cleaning fluid discharging unit is allowed to adhere and another surface of the member meet.

14. The substrate processing apparatus of claim 13,
wherein the member within the processing chamber on which the R chamfering is performed includes a bottom plate provided between a sidewall of the processing chamber and a cup configured to surround the substrate holding unit and collect the processing liquid scattered from the substrate.

15. A processing chamber cleaning method of cleaning a cleaning target within a processing chamber of a substrate processing apparatus, the processing chamber cleaning method comprising:
a cleaning process of cleaning a removal target adhering to a surface of the cleaning target by discharging water into the processing chamber and allowing the cleaning target to be wet with the water;
a solvent supplying process of supplying a solvent having higher volatility than the water toward the water adhering to the surface of the cleaning target by discharging the solvent into the processing chamber; and
a drying process of drying the surface of the cleaning target.

16. The processing chamber cleaning method of claim 15,
wherein the water is discharged into the processing chamber in a form of mist in the cleaning process, and
the solvent is discharged into the processing chamber in a form of mist in the solvent supplying process.

17. The processing chamber cleaning method of claim 15,
wherein the solvent is supplied in a heated state in the solvent supplying process.

18. The processing chamber cleaning method of claim 15,
wherein a nitrogen gas is supplied into the processing chamber in the drying process.

19. The processing chamber cleaning method of claim 15,
wherein, in the drying process, by holding a cleaning jig by a substrate holding unit provided within the processing chamber and rotating the cleaning jig, an air flow is generated in a space above the cleaning jig, and
drying of the cleaning target to which the solvent or the water adheres is accelerated by the air flow.

20. The processing chamber cleaning method of claim 19,
wherein, in the drying process, by locating a nozzle arm, which is configured to hold a processing fluid nozzle configured to supply a processing fluid onto a substrate, above the cleaning jig, drying of a bottom surface of the nozzle arm to which the solvent or the water adheres is accelerated.

21. The processing chamber cleaning method of claim 15,
wherein, in the drying process, a wall of the processing chamber is heated by a heater provided at the wall.
